(19) United States
(12) Patent Application Publication
(10) Pub. No.: US 2016/0093633 A1
(43) Pub. Date: Mar. 31, 2016

(54) SEMICONDUCTOR MEMORY DEVICE AND MANUFACTURING METHOD THEREOF

(71) Applicant: KABUSHIKI KAISHA TOSHIBA, Tokyo (JP)

(72) Inventor: Takayuki TOBA, Yokkaichi Mie (JP)

(21) Appl. No.: 14/626,314

(22) Filed: Feb. 19, 2015

(30) Foreign Application Priority Data
Sep. 30, 2014 (JP) 2014-202638

(51) Int. Cl. H01L 27/115; H01L 29/423; H01L 29/10; H01L 23/528

(52) U.S. Cl. CPC H01L 27/11546; H01L 27/11524; H01L 27/11529; H01L 27/1157; H01L 27/11573; H01L 23/528; H01L 29/42364; H01L 29/42376; H01L 29/1033

(57) ABSTRACT

A semiconductor memory device includes a plurality of memory cell transistors that are formed above a semiconductor substrate and are connected to each other in series, first and second selection transistors formed respectively on either side of the memory cell transistors above the semiconductor substrate, a source line contact formed adjacent the first selection transistor and having a bottom thereof in contact with the semiconductor substrate, and a bit line contact formed adjacent the second selection transistor and having a bottom thereof in contact with the semiconductor substrate at a position higher than the bottom of the source line contact.

### CROSS-REFERENCE TO RELATED APPLICATION

This application is based upon and claims the benefit of priority from Japanese Patent Application No. 2014-202638, filed Sep. 30, 2014, the entire contents of which are incorporated herein by reference.

### FIELD

Embodiments described herein relate generally to a semiconductor memory device and a manufacturing method thereof.

### BACKGROUND

A semiconductor memory device has been developed with enlarged capacity and miniaturized dimensions. To further achieve miniaturization, it is necessary to miniaturize the size of wirings and contacts. Among contacts, bit line contacts and source line contacts occupy a large area of a storage device, and there is a growing need to achieve miniaturization in the size of these contacts.

When contacts are miniaturized, it is known that pattern formation and process control become difficult. One reason is that the bit line contact and the source line contact require different opening areas and, as a result, different etching speeds, and a simultaneous process is therefore difficult.

### DESCRIPTION OF THE DRAWINGS

FIG. 1 is a block diagram illustrating a configuration of a semiconductor device according to a first embodiment.

FIG. 2 is a schematic plan view of the semiconductor device according to the first embodiment.

FIG. 3 is a schematic circuit diagram illustrating a memory cell array of the semiconductor device according to the first embodiment.

FIG. 4 is a schematic plan layout view illustrating the memory cell array of the semiconductor device according to the first embodiment.

FIG. 5 is a schematic cross-sectional view illustrating the semiconductor device according to the first embodiment.

FIGS. 6-31 are schematic cross-sectional views illustrating the semiconductor device according to the first embodiment at different steps of a manufacturing process therefor.

FIGS. 32-34 are schematic cross-sectional views illustrating modification examples of the first embodiment.

### DETAILED DESCRIPTION

Embodiments provide a low power consumption semiconductor memory device and a manufacturing method thereof.

In general, according to one embodiment, a semiconductor memory device includes a plurality of memory cell transistors that are formed above a semiconductor substrate and are connected to each other in series, first and second selection transistors formed respectively on either side of the memory cell transistors above the semiconductor substrate, a source line contact formed adjacent the first selection transistor and having a bottom thereof in contact with the semiconductor substrate, and a bit line contact formed adjacent the second selection transistor and having a bottom thereof in contact with the semiconductor substrate at a position higher than the bottom of the source line contact.

Hereinafter, exemplary embodiments will be described with reference to drawings.

In a following description, a side close to a semiconductor substrate side is described as a lower side for convenience of description.

### First Embodiment

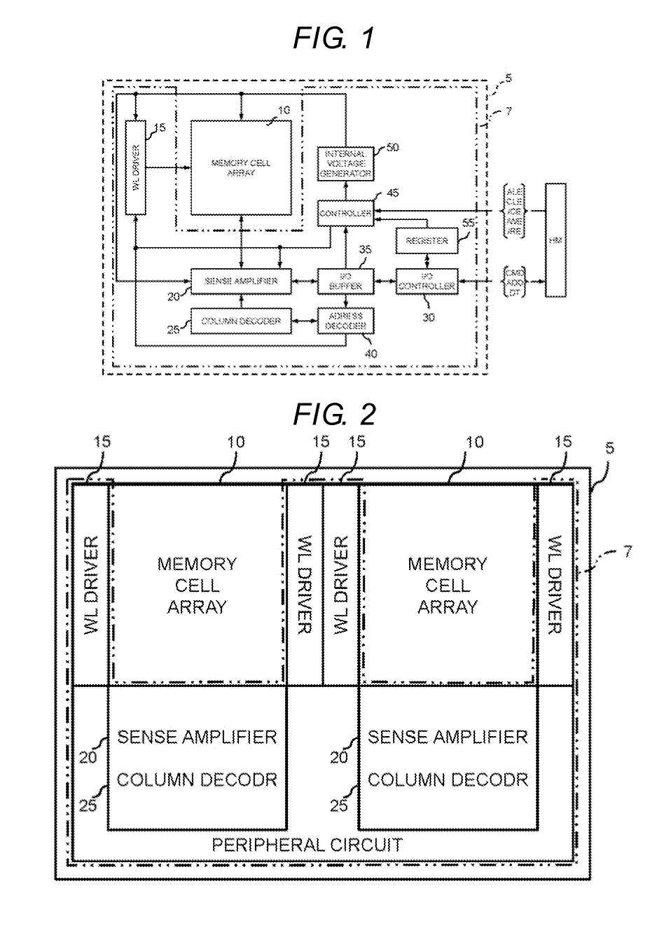

As a first embodiment, a NAND-type flash memory is described as an example. FIG. 1 is a block diagram illustrating a configuration of a semiconductor memory device 5 according to the first embodiment.

The semiconductor memory device 5 includes a memory cell array 10 and a peripheral circuit 7. The memory cell array 10 stores data. In addition, the memory cell array 10 performs various operations such as reading and writing data in response to an input from the peripheral circuit 7. The peripheral circuit 7 provides a necessary voltage for the memory cell array 10 in response to an input from outside, and performs various operations for functioning of the semiconductor memory device 5.

In the memory cell array 10, a plurality of memory cells are disposed in a matrix shape. A memory cell has an EEPROM cell which is electrically rewritable. The memory cell array 10 includes a plurality of bit lines, a plurality of word lines, and a source line so as to control a voltage of a memory cell.

The peripheral circuit 7 includes a word line driver 15, a sense amplifier 20, a column decoder 25, an input/output controller 30, an input/output buffer 35, an address decoder 40, a controller 45, an internal voltage generator 50, and a register 55 as illustrated in FIG. 1 as an example.

The word line driver 15 is connected to a plurality of word lines of the memory cell array 10. The word line driver 15 selects and drives a word line when reading, writing, and erasing data based on an output signal of the address decoder 40.

The sense amplifier 20 detects data of a bit line when reading data. In addition, the sense amplifier 20 applies a voltage corresponding to written data when writing data to a bit line.

The column decoder 25 generates a column selection signal for selecting a bit line and transmits the column selection signal to the sense amplifier 20 based on an output signal of the address decoder 40.

The input/output controller 30 receives various commands CMD, address signals ADD, and data DT (including written data) which are provided from outside.

Specifically, when writing data, written data are transmitted to the sense amplifier 20 through the input/output controller 30 and the input/output buffer 35. In addition, when reading data, read data read by the sense amplifier 20 are transmitted to the input/output controller 30 through the input/output buffer 35. Then, the read data are output to an external HM (for example, a memory controller or a host) through the input/output controller 30.

An address signal ADD transmitted from the input/output controller 30 to the input/output buffer 35 is transmitted to the address decoder 40. The address decoder 40 decodes the address signal ADD, transmits a row address to a word line driver 15, and transmits a column address to a column decoder 25.

A command CMD transmitted from the input/output controller 30 to the input/output buffer 35 is transmitted to the controller 45.

The controller 45 is provided with external control signals such as a chip enable signal /CE, a write enable signal /WE, a read enable signal /RE, an address latch enable signal ALE, a command latch enable signal CLE from the external HM.

The controller 45 generates a control signal which controls a sequence of writing and erasing data, and a control signal which controls reading of data based on an external control signal provided according to an operation mode and a command CMD. The control signal is transmitted to the word line driver 15, the sense amplifier 20, the internal voltage generator 50, and the like. The controller 45 generally controls various operations of the semiconductor memory device 5 using the control signal.

The controller 45 does not have to be disposed in the semiconductor memory device 5. That is, the controller 45 may be disposed in a semiconductor device other than the semiconductor memory device 5, and may be disposed in an external HM.

The internal voltage generator 50 generates a voltage necessary for various operations of the memory cell array 10, the word line driver 15, and the sense amplifier 20, such as a read voltage, a write voltage, a verify voltage, and an erase voltage according to various control signals transmitted from the controller 45.

The register 55 is connected to the input/output controller 30 and the controller 45, and stores a parameter suitable for a quality of chip which is determined by a test process.

FIG. 2 is a schematic plan view illustrating the semiconductor memory device 5 according to the first embodiment illustrated in FIG. 1.

Two memory cell arrays 10 are provided in the semiconductor memory device 5. In addition to a region of the memory cell array 10, the peripheral circuit 7 is formed therein.

As the peripheral circuit 7, the word line driver 15, the sense amplifier 20, and the column decoder 25 are provided to be in contact with the memory cell array 10. Moreover, the input/output controller 30, the input/output buffer 35, the address decoder 40, the controller 45, the internal voltage generator 50, the register 55, and the like illustrated in FIG. 1 are formed in the other regions.

These peripheral circuits include two or more transistors which have different operation voltages. For convenience of description, a transistor whose operation voltage is low is referred to as a low voltage transistor, and a transistor whose operation voltage is high is referred to as a high voltage transistor. The low voltage transistor and the high voltage transistor have different film thicknesses of a gate insulating film due to a difference in an operation voltage.

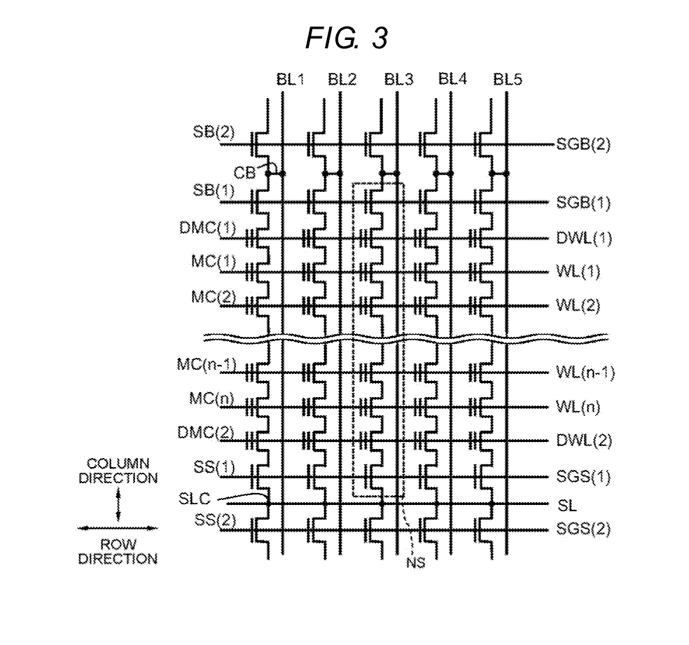

FIG. 3 illustrates an example of a configuration of a NAND-type flash memory. FIG. 3 is a schematic circuit diagram illustrating a part of the memory cell array 10 of the NAND-type flash memory.

In FIG. 3, BL1 to BL5 indicate a bit line, WL (1) to WL (n) indicate a word line (control gate), and DWL (1) and DWL (2) indicate a dummy word line, SGB (1) and SGB (2) indicate a selection gate line of the bit line side selection transistor, SGS (1) and SGS (2) indicate a selection gate line of the source line side selection transistor, and SL indicates a source line. MC (1) to MC (n) indicate a memory cell (referred to as memory cell transistor), DMC (1) and DMC (2) indicate a dummy memory cell (referred to as a dummy memory cell transistor), SB (1) and SB (2) indicate the bit line side selection transistor, SS (1) and SS (2) indicate the source line side selection transistor, CB indicates a bit line contact, and SLC indicates a source line contact.

When distinction is not required, MC (1) to MC (n), DMC (1) and DMC (2), SB (1) and SB (2), SS (1) and SS (2), CB, and SLC are referred to as the memory cell MC, the dummy memory cell DMC, the bit line side selection transistor SB, the source line side selection transistor SS, the bit line BL, the word line WL, the selection gate line SGB, and the selection gate line SGS. Moreover, the dummy memory cell transistor DMC and the memory cell transistor MC are collectively referred to as a cell transistor. Furthermore, the bit line side selection transistor SB and the source line side selection transistor SS are collectively referred to as a selection transistor.

As illustrated in FIG. 3, the memory cell array 10 includes a plurality of NAND strings NS.

Each NAND string NS includes m memory cells MC (1) to MC (n) which are connected in series, and two dummy memory cells DMC (1) and DMC (2) connected to each of both ends of each NAND string NS, and further includes the bit line side selection transistor SB (1) and the source line side selection transistor SS (1) each connected to the both ends.

The other end of the bit line side selection transistor SB (1) is connected to one end of a bit line side selection transistor SB (2) of another NAND string NS, and is connected to a bit line BL through a bit line contact CB. The other end of the source line side selection transistor SS (1) is connected to one end of a source line side selection transistor SS (2) of another NAND string NS, and is connected to a source line SL through the source line contact SLC.

The memory cell MC includes a charge accumulation film (for example, a floating gate electrode and an insulation film having a trap are considered, or alternatively, a laminated film of these may be considered) formed on the semiconductor substrate (well) through a gate insulating film, and a control gate electrode which is formed on the charge accumulation film through an insulation film between gates. The memory cell MC may store data of 1.5 bit (3 value or more) in, for example, one memory cell MC according to a change in a threshold voltage due to an amount of electrons implanted into the charge accumulation film.

The dummy memory cell DMC includes a film the same as the memory cell MC. However, the dummy memory cell DMC may not necessarily preserve data from a user of the semiconductor memory device 5.

The bit line side selection transistor SB and the source line side selection transistor SS control selection or non-selection of the NAND string NS.

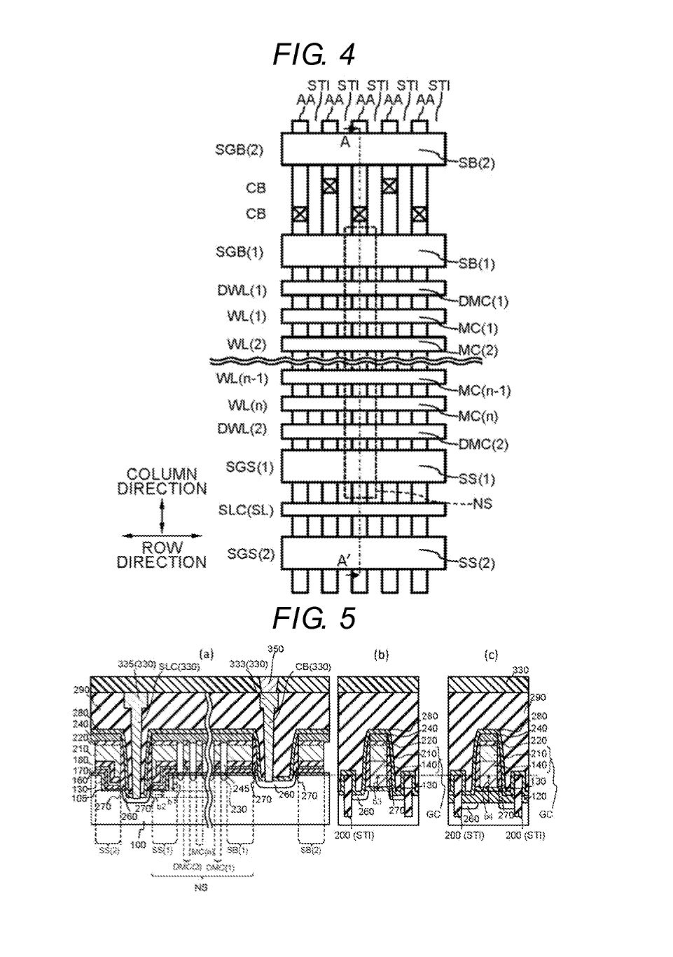

FIG. 4 is a schematic plan view illustrating the memory cell array of the NAND-type flash memory illustrated in FIG. 3. In a following description, an extending direction of a bit line is referred to as a column direction, and an extending direction of a word line is referred to as a row direction.

As illustrated in FIG. 4, a plurality of active areas AA extending in the column direction are formed. The active areas AA are provided to be isolated from each other by an element isolating area STI.

The word lines WL (1) to WL (n), the dummy word lines DWL (1) and DWL (2), the selection gate lines SGB (1), SGB (2), SGS (1), and SGS (2) are formed to be extended in a row direction so as to be substantially orthogonal to an active area AA. At an intersection between the active area AA and the word lines WL (1) to WL (n), the memory cells MC (1) to MC (n) are formed. In the same manner, at an intersection between the dummy word lines DWL (1) and DWL (2), the dummy memory cells DMC (1) and DMC (2) are formed. At an intersection between the selection gate lines SGB (1) and SGB (2), the bit line side selection transistors SB (1) and SB (2) are formed. At an intersection between the selection gate lines SGS (1) and SGS (2), the source lie side selection transistors SS (1) and SS (2) are formed.

The source line SL is formed by being extended in a row direction to be substantially orthogonal to the active area AA. The source line SL is connected to the active area AA through the source line contact SLC. The source line contact SLC is across the active area in a row direction to be formed in a line shape as illustrated in FIG. 4.

The bit line contact CB connects each bit line (not illustrated) and each active area AA. Therefore, the bit line contact CB is formed in a plug shape for each active region unlike the source line contact SLC.

That is, as apparent from FIG. 4, the source line contact SLC has larger area than the bit line contact CB in a plan view.

FIG. 5 is a schematic cross-sectional view illustrating the semiconductor memory device according to the embodiment. Part (a) of FIG. 5 schematically shows a cross-sectional view taken along line A-A′ of FIG. 4. Part (a) of FIG. 5 omits more parts than FIG. 4 for convenience of description.

Part (b) of FIG. 5 schematically illustrates a cross-sectional view of a low voltage transistor. Part (c) of FIG. 5 schematically illustrates a cross-sectional view of a high voltage transistor. The low voltage transistor and the high voltage transistor are transistors formed in the peripheral circuit 7 illustrated in FIG. 2.

First, a memory cell array region will be described using part (a) of FIG. 5. The recess 105 provided between the source line side selection transistor SS (1) and the source line side selection transistor SS (2) will be described below.

In the structure shown in part (a) of FIG. 5, memory cells MC (1) to MC (n) are formed on the semiconductor substrate 100 side by side and are located in the center of the structure (but not illustrated). On both sides of the memory cell MC (1) to the memory cell MC (n), dummy memory cells DMC (1) and DMC (2) are formed, respectively. Furthermore, a bit line side selection transistor SB (1) and a source line side selection transistor SS (1) are formed on the both sides.

In other words, the memory cells MC (1) to MC (n) are provided between the dummy memory cells DMC (1) and DMC (2). The dummy memory cell DMC (1) is provided between the memory cell MC (1) and the bit line side selection transistor SB (1). The dummy memory cell DMC (2) is provided between the memory cell MC (n) and the source line side selection transistor SS (1).

First impurity diffusion layers 230 are formed in a source/drain region between these memory cells MC (1) to MC (n), the dummy memory cells DMC (1) and DMC (2), and the bit line side selection transistor SB (1) and a source line side selection transistor SS (1). Respective source/drain regions are connected to each other through the first impurity diffusion layer 230.

A source region of the bit line side selection transistor SB (1) is connected to a source region of the dummy memory cell DMC (1). A drain region of the bit line side selection transistor SB (1) is connected to a drain region of the bit line side selection transistor SB (2), and is connected to the bit line contact CB.

The bit line contact CB is connected to a bit line (not shown) through a first wiring contact 333 on an upper layer.

A drain region of the source line side selection transistor SS (1) is connected to a source region of the dummy memory cell DMC (2) as described above. A source region of the source line side selection transistor SS (1) is connected to a source region of the source line side selection transistor SS (2), and is connected to the source line contact SLC.

The source line contact SLC is connected to a first wiring (source line) 335.

Subsequently, a more detailed structure of each element will be described.

Gate insulating films and gate electrodes of the memory cells MC (1) to MC (n), the dummy memory cells DMC (1) and DMC (2), the selection transistors SS (1) and SS (2) on a source line side, and the bit line side selection transistors SB (1) and SB (2) have a structure which includes the same film.

These transistors include a second gate insulating film 130, a first memory gate insulating film 160, a charge accumulation film 170, a second memory gate insulating film 180, and a conductive film 210. A cover film 220, an insulation film 240, and a stopper film 280 are provided on gate electrodes of these transistors.

In one example, the second gate insulating film 130 is a silicon oxide film, the first memory gate insulating film 160 is a silicon oxide film, the charge accumulation film 170 is a silicon film, the second memory gate insulating film 180 is a lamination of a hafnium oxide film and a silicon oxide film, the conductive film 210 is a tungsten film, the cover film 220 is a silicon nitride film, the insulation film 240 is a silicon oxide film, and the stopper film 280 is a silicon nitride film.

A spacer 270 and a stopper film 280 are formed on a side wall of the bit line side selection transistor SB on a bit line contact CB side, and a side wall of the source line side selection transistor SS on a source line contact SLC side.

A gap 245 is formed between the bit line side selection transistor SB and the source line side selection transistor SS and the dummy memory cell DMC, between the dummy memory cell DMC and the memory cell MC, and between the memory cells MCs, respectively.

The bit line contact CB and the source line contact SLC have, for example, a metal film and a barrier metal film. The metal film includes a conductive metal such as tungsten, aluminum, or copper. The barrier metal film includes, for example, titanium, tantalum, titanium nitride, and tantalum nitride, or is a laminated film of any of these. Moreover, a silicon film may be used in addition to the metal film and the barrier metal film.

Next, using parts (b) and (c) of FIG. 5, a low voltage transistor and a high voltage transistor will be described.

An element isolating area STI is provided on the semiconductor substrate 100.

In addition, in the low voltage transistor, the second gate insulating film 130 is provided on the semiconductor substrate 100, and a gate electrode GC is provided thereon. On the other hand, in the high voltage transistor, a first gate insulating film 120 and the second gate insulating film 130 are provided on the semiconductor substrate 100, and the gate electrode GC is provided thereon. That is, configurations of a gate insulating film in the low voltage transistor and the high voltage transistor are different. The first gate insulating film 120 and the second gate insulating film are, for example, a silicon oxide film.

A second impurity diffusion layer 260 is formed on the semiconductor substrate 100 so as to interpose a region directly under the gate electrode GC.

Either gate electrode GC of the gate electrodes GC of the low voltage transistor and the high voltage transistor, includes, for example, the peripheral gate electrode film 140 and the conductive film 210. The cover film 220, the insulation film 240, and the stopper film 280 are provided on the gate electrode. The spacer 270 and the stopper film 280 are provided on a side wall of the gate electrodes of these transistors.

Subsequently, a height of an upper surface of the semiconductor substrate 100 in the recess 105 and each region will be described using parts (a) to (c) of FIG. 5. In the following description, for the sake of convenience, a height of a surface of the semiconductor substrate 100 in a region in which the memory cell MC is formed is described as a reference. That is, for example, a surface of the semiconductor substrate 100 that is positioned higher than the surface of the semiconductor substrate 100 in a region in which the memory cell MC (1) is formed, is referred to as “high”, and a surface of the semiconductor substrate 100 that is positioned lower than the surface of the semiconductor substrate 100 in a region in which the memory cell MC (1) is formed, is referred to as “low” or “deep”.

As illustrated in part (a) of FIG. 5, in a part of a region in which source line side selection transistors SS (1) and SS (2) are formed and in a region between the source line side selection transistor SS (1) and the source line side selection transistor SS (2), the semiconductor substrate 100 has a recess 105 formed to be recessed on a surface thereof lower than a surrounding. A depth of the recess 105 is set to be b1.

Since the semiconductor substrate 100 has the recess 105, the source line side selection transistors SS (1) and SS (2) are formed in a curved shape as illustrated in part (a) of FIG. 5. That is, a gate electrode, a gate insulating film, a channel region of the source line side selection transistors SS (1) and SS (2) are formed in a curved shape.

A length of the channel region of the source line side selection transistor SS which is curved is longer than one when formed in a flat manner as the bit line side selection transistor SB. As a result, the source line side selection transistor SS is improved in controllability.

Between the spacers 270 of the source line side selection transistors SS (1) and SS (2), the semiconductor substrate 100 is low. A depth is set to be b1+b2.

Subsequently, a region in which the low voltage transistor of part (b) of FIG. 5 is formed will be described.

The semiconductor substrate 100 under the gate electrode GC of the low voltage transistor is also formed to be low, and the depth is set to be b3.

Here, as described later, since b3 and b1 are made by an etching process of the same RIE, b3 and b1 are substantially the same as each other. In each region, a film formed on the semiconductor substrate 100 is different. Accordingly, elements making up the semiconductor substrate 100 are differently diffused from the semiconductor substrate 100, and thereby a difference of about several nm occurs.

A region in which the high voltage transistor of part (c) of FIG. 5 is formed is now described. The semiconductor substrate 100 under the gate electrode GC of the high voltage transistor is also formed to be low, and the depth is set to be b4.

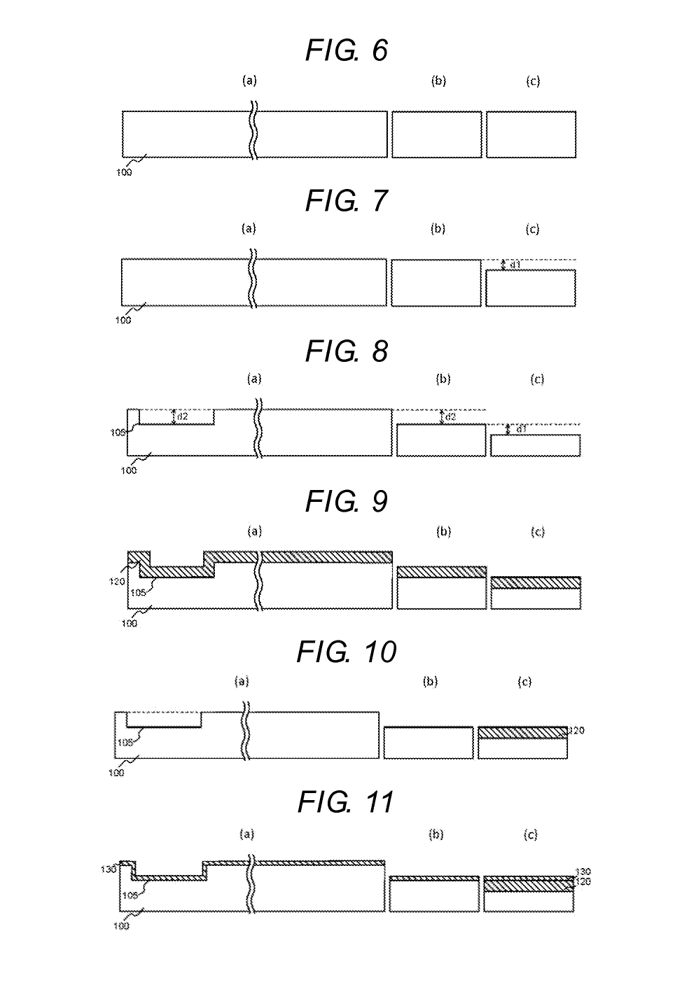

Hereinafter, a manufacturing method of the semiconductor memory device according to the embodiment will be described with reference to FIGS. 6 to 29. In FIGS. 6 to 29, each part (a) illustrates a cross-section taken along line A-A′ (column direction) of FIG. 4, each part (b) illustrates across-section of the low voltage transistor of a peripheral circuit unit, and each part (c) illustrates a cross-section of the high voltage transistor of the peripheral circuit unit. For convenience, hereinafter, each is referred to as a memory cell region, a low voltage transistor region, and a high voltage transistor region. In addition, FIGS. 6 to 29 have an aspect ratio different from that in FIG. 5.

First, a state of the semiconductor substrate 100 is illustrated in FIG. 6. Each of the memory cell region, the low voltage transistor region, and the high voltage transistor region has the same height as the semiconductor substrate 100.

Then, to form the structure illustrated in FIG. 7, a mask pattern which is not illustrated is formed on the semiconductor substrate 100 and an etching process is performed on the high voltage transistor region by RIE. A depth to which the etching process is performed is set to be d1.

Then, to form the structure illustrated in FIG. 8, a mask pattern which is not shown is formed on the semiconductor substrate 100, and the etching process is performed by RIE. The high voltage transistor region and the low voltage transistor region are processed by the etching process, and the recess 105 is formed in the memory cell region. A depth to which the etching process is performed is set to be d2.

Thereafter, a P-type and an N-type well (not illustrated) are formed by forming a sacrificial oxide film which is not illustrated and implanting impurities in an implantation method.

Then, to form the structure illustrated in FIG. 9, the first gate insulating film 120 is formed after removing the sacrificial oxide film 110. The first gate insulating film 120 is, for example, a silicon oxide film, a silicon oxynitride film, and the like.

Then, to form the structure illustrated in FIG. 10, a mask pattern which is not illustrated is formed, and then the first gate insulating film 120 other than the portion in the high voltage transistor region is etched by a chemical solution such as hydrofluoric acid.

Then, to form the structure illustrated in FIG. 11, the second gate insulating film 130 is formed on the semiconductor substrate 100 and the first gate insulating film 120. The second gate insulating film 130 is, for example, a silicon oxide film, a silicon oxynitride film, and the like.

Accordingly, the first gate insulating film 120 and the second gate insulating film 130 are formed in the high voltage transistor region. On the other hand, the second gate insulating film 130 is formed in the low voltage transistor region and the memory cell region.

It is desirable that a height at an upper end of the second gate insulating film 130 in the low voltage transistor region be substantially the same as one in the high voltage transistor region. The height is realized by adjusting d1 which is a depth of etching and a thickness of the first gate insulating film 120.

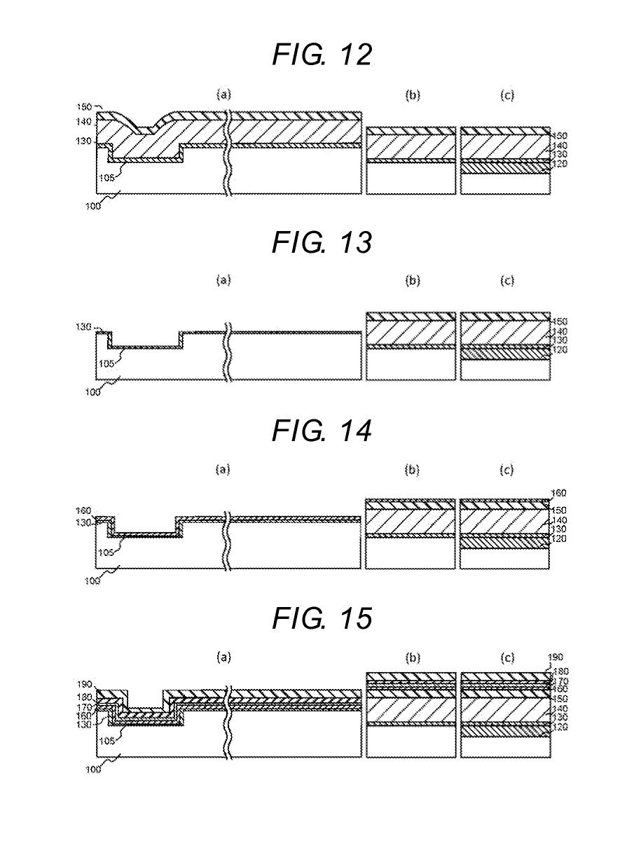

Then, to form the structure illustrated in FIG. 12, the peripheral gate electrode film 140 and the peripheral cover film 150 are formed on the second gate insulating film 130. The peripheral gate electrode film 140 is, for example, a polycrystalline silicon. The peripheral cover film 150 is, for example, a silicon nitride film.

Then, to form the structure illustrated in FIG. 13, a mask pattern which is not illustrated is formed, and then the peripheral cover film 150 and the peripheral gate electrode film 140 are etched by RIE. As illustrated in part (a) of FIG. 13, the peripheral cover film 150 and the peripheral gate electrode film 140 of the memory cell region are removed by this processing. The second gate insulating film 130 of the region in which the memory cell MC is formed may also be removed by an etching.

Then, to form the structure illustrated in FIG. 14, the first memory gate insulating film 160 is formed. The first memory gate insulating film 160 is, for example, a silicon oxide film, a silicon oxynitride film, a silicon nitride film, a hafnium oxide film, a hafnium nitride film, a hafnium oxynitride film, an aluminum oxide film, an aluminum nitride film, an aluminum oxynitride film, or a laminated film of any these.

Then, to form the structure illustrated in FIG. 15, the charge accumulation film 170, the second memory gate insulating film 180, and the cell array cover film 190 are formed on the first memory gate insulating film 160. The charge accumulation film 170 is, for example, a silicon film, a silicon nitride film, or the like.

The second memory gate insulating film 180 is, for example, a silicon oxide film, a silicon oxynitride film, a silicon nitride film, a hafnium oxide film, a hafnium nitride film, a hafnium oxynitride film, an aluminum oxide film, an aluminum nitride film, an aluminum oxynitride film, or a laminated film of any of these. In addition, the second memory gate insulating film 180 may include other metal elements. The cell array cover film 190 is, for example, a silicon nitride film.

Here, it is desirable that an upper end of the second memory gate insulating film 180 of the memory cell region and an upper end of the peripheral gate electrode film 140 of the low voltage transistor region and the high voltage transistor region be formed to have the same height as each other. The height may be realized by, for example, adjusting d2 which is a depth of etching and a thickness of the peripheral gate electrode film 140.

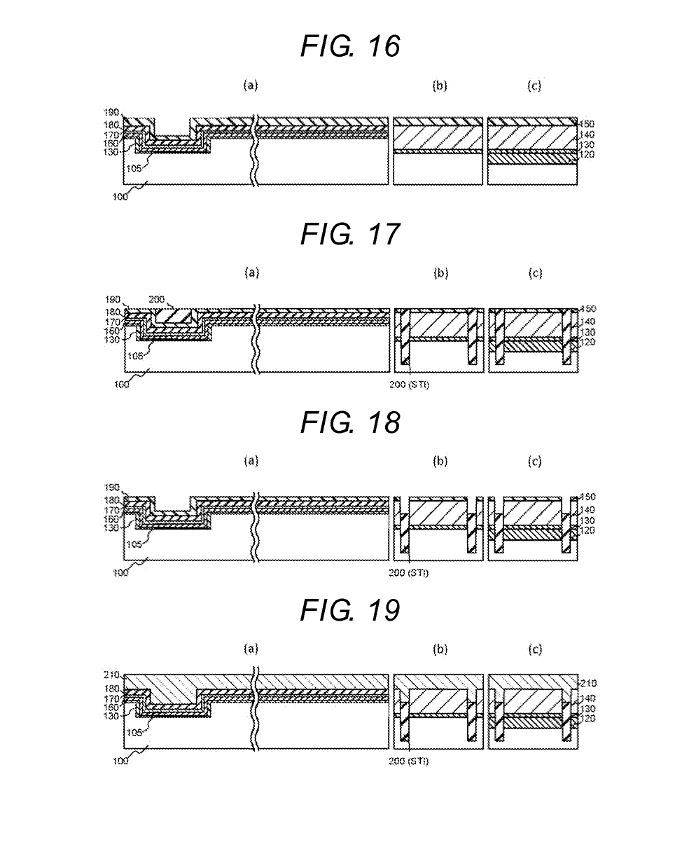

Then, to form the structure illustrated in FIG. 16, a desirable mask pattern is formed, and then the cell array cover film 190, the second memory gate insulating film 180, the charge accumulation film 170, and the first memory gate insulating film 160 are etched by RIE in regions other than the memory cell region. The cell array cover film 190, the second memory gate insulating film 180, the charge accumulation film 170, and the first memory gate insulating film 160 of the low voltage transistor region and the high voltage transistor region are removed by this processing.

Here, it is desirable that the peripheral cover film 150 in the low voltage transistor region and the high voltage transistor region have substantially the same height as the upper end of the cell array cover film 190 of the memory cell region. This is achieved, for example, by adjusting the above-mentioned etching process, a thickness of the peripheral cover film 150, and a thickness of the cell array cover film 190.

Then, to form the structure illustrated in FIG. 17, an element isolating area STI is formed.

A mask pattern is formed on the peripheral cover film 150 and the cell array cover film 190 by a lithography method. The mask pattern is set as a mask material, and the semiconductor substrate 100 is etched to a predetermined depth by RIE. Thereafter, the element isolation film. 200 is formed. Flattening is performed by Chemical Mechanical Polishing (CMP) in which the peripheral cover film 150 and the cell array cover film 190 are set as a stopper, whereby extra element isolation film 200 is removed to flatten the upper surface. Accordingly, the element isolating area STI is formed.

The element isolating area STI is formed in a stripe shape parallel in the column direction illustrated in FIG. 4 in the memory cell region. In addition, the element isolating area STI is formed in the low voltage transistor region and the high voltage transistor region as illustrated in FIG. 17.

Then, to form the structure illustrated in FIG. 18, the element isolation film 200 is etched to a predetermined depth by a selective etching process by RIE. As illustrated in FIG. 18, it is desirable that the element isolation film 200 in the recess 105 formed in the memory cell region be removed.

Then, to form the structure illustrated in FIG. 19, the peripheral cover film 150 and the cell array cover film 190 are removed using, for example, a phosphoric acid. Then, the conductive film 210 is formed. When necessary, flattening may be performed by CMP.

The conductive film 210 includes, for example, silicon, titanium, titanium nitride, tungsten, nitride tungsten, or is a laminated film of any of these.

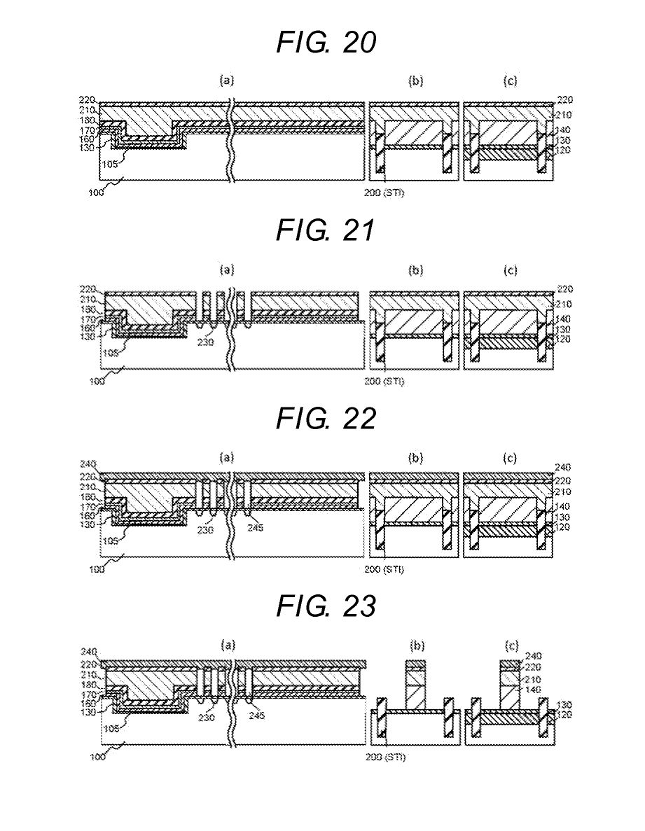

Then, as illustrated in FIG. 20, the cover film 220 is formed on the conductive film 210. The cover film 220 is, for example, a silicon nitride film.

Then, a process is performed on a gate electrode of a transistor. Here, as an example, a method of differently processing the memory cell MC, the selection transistor, and the peripheral circuit transistor is described.

First, to form the structure illustrated in FIG. 21, a process is performed on the memory cell MC.

A mask pattern is formed on the cover film 220 by the lithography method. The mask pattern is set to be a mask, and the etching process is performed by RIE. The cover film 220, the conductive film 210, the second memory gate insulating film 180, the charge accumulation film 170, and the first memory gate insulating film 160 are etched by the process. Then, the first impurity diffusion layer 230 is formed by implanting an impurity element in an implantation method.

During the above-mentioned etching process, the second gate insulating film 130 may be etched. In addition, when necessary, a mask material may be formed on the cover film 220, and a mask pattern may be formed on the mask material. In this case, the mask material may be used up during the etching process or may remain.

During implanting the impurity element, a mask is formed by the lithography method and the like in advance, and the impurity element may be divided for each region. In FIG. 21, the impurity element is illustrated as the first impurity diffusion layer 230 without distinction.

Then, to form the structure illustrated in FIG. 22, the insulation film 240 with a poor coverage is formed on the cover film 220 to form a gap 245. For example, the insulation film 240 is a silicon oxide film or a silicon nitride film according to a film-forming condition with a poor coverage by a sputtering method or a Plasma-Enhanced Chemical Vapor Deposition (PECVD) method.

Then, as illustrated in FIG. 23, a process is performed on the low voltage transistor and the high voltage transistor. Using a lithography method on the insulation film 240, a mask pattern is formed. The mask pattern is set to be a mask, whereby the insulation film 240, the cover film 220, the conductive film 210, and the peripheral gate electrode film 140 are etched by RIE. The second gate insulating film 130 and the first gate insulating film 120 may be processed. In addition, an impurity element may be implanted by an implantation method.

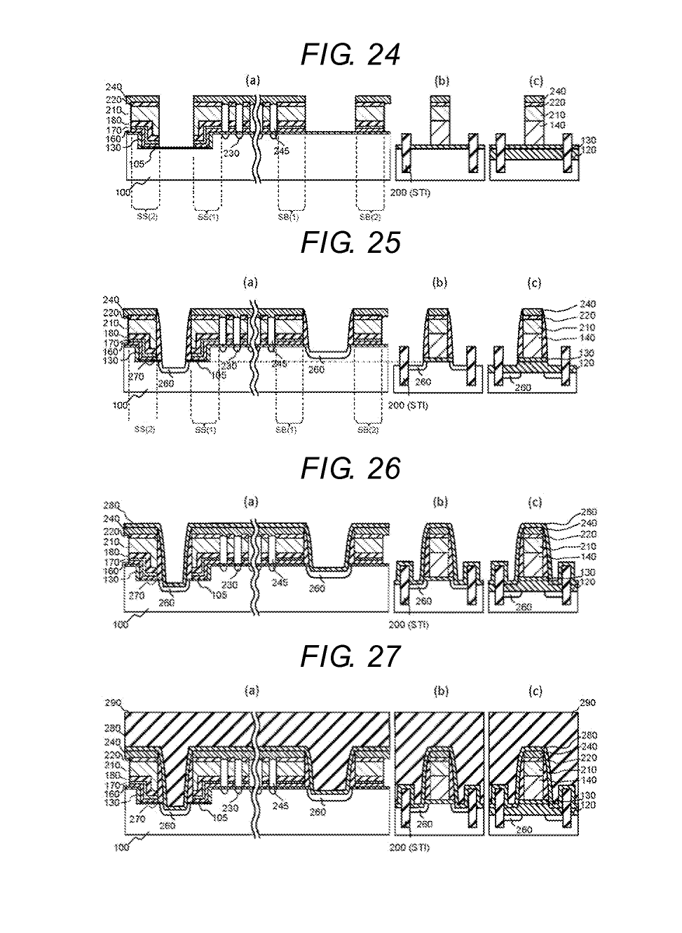

Then, to form the structure illustrated in FIG. 24, a process of the selection transistor is performed.

The mask pattern is formed using the lithography method. The mask pattern is set to be a mask, the insulation film 240, the cover film 220, the conductive film 210, the second memory gate insulating film 180, the charge accumulation film 170, and a first memory gate insulating film 160 are etched by RIE. The second gate insulating film 130 may be processed. Moreover, after processing, an impurity element may be implanted by the implantation method after the process.

In the process of forming the selection transistor, to form the structure illustrated in FIG. 24, a process between source line side selection transistors SS is necessarily performed deeper than a process between bit line side selection transistors SB. For example, the etching process may be realized by performing an etching according to a condition which takes into account a selection ratio between the conductive film 210 and the second memory gate insulating film 180 during etching.

That is, when an etching process between the bit line side selection transistors SB reaches the second memory gate insulating film 180, an etching speed between the bit line side selection transistors SB is slow, such that it is possible to proceed with only the process between the source line side selection transistors SS. Then, after the etching process between the source line side selection transistors SS reaches the second memory gate insulating film 180, an etching speed of the second memory gate insulating film 180 may be switched to be fast.

Then, to form the structure illustrated in FIG. 25, the spacer (side wall) 270 is formed to be etched back by RIE after the spacer film is formed. Furthermore, the second impurity diffusion layer 260 is formed by implanting an impurity element in the implantation method.

As a result of the etching-back process, as illustrated in FIG. 25, the semiconductor substrate 100 is etched in a region between the spacer 270 of the bit line side selection transistor SB (1) and the spacer 270 of the bit line side selection transistor SB (2), a region between the spacer 270 of the source line side selection transistor SS (1) and the spacer 270 of the source line side selection transistor SS (2), and the low voltage transistor region. On the other hand, the second gate insulating film 130 and the first gate insulating film 120 are etched in the high voltage transistor region. The recess 105 has a deeper region (a first region) and a second region shallower than the first region due to the etching process.

The spacer film is, for example, a silicon oxide film, a silicon nitride film, or a laminated film of any of these. When implanting an impurity element, a mask is formed in advance by the lithography method and the like, whereby the impurity element may be divided for each region. In FIG. 25, the second impurity diffusion layer 260 is illustrated without distinction.

Then, to form the structure illustrated in FIG. 26, the stopper film 280 is formed. The stopper film 280 is, for example, a silicon oxide film, a silicon nitride film, or a laminated film of any of these.

Then, to form the structure illustrated in FIG. 27, the first interlayer insulation film 290 is formed, and is flattened by CMP when necessary. The first interlayer insulation film 290 is, for example, a silicon oxide film.

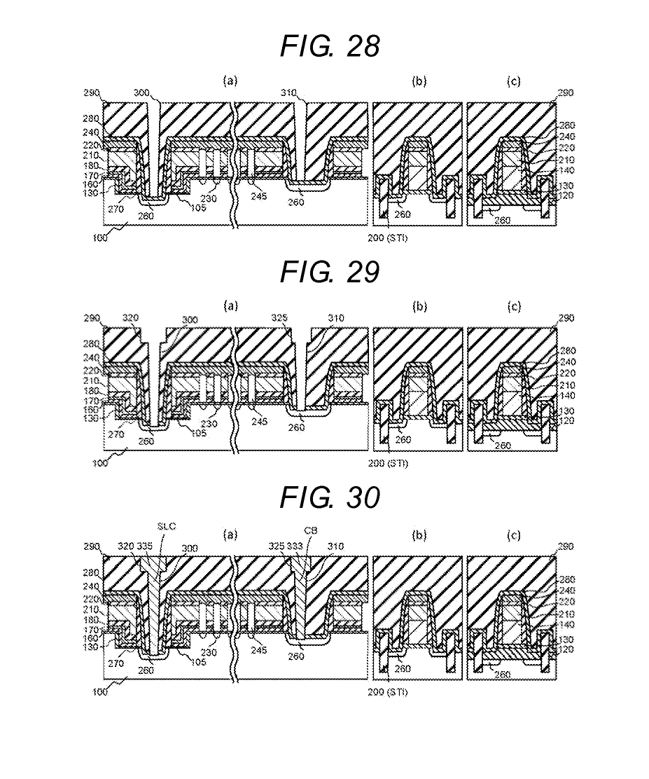

Then, to form the structure illustrated in FIG. 28, a resist pattern is formed on the first interlayer insulation film 290 by the lithography method. The resist pattern is set to be a mask, and the first interlayer insulation film 290 is etched by RIE so as to reach the stopper film 280. The trench for source line contact 300 and the hole for bit line contact 310 are formed by this process. At the same time, a contact hole (not illustrated) may be formed in a source region and a drain region of the low voltage transistor and the high voltage transistor.

The trench for source line contact is formed in a line shape in a row direction as illustrated in FIG. 4. In contrast, the bit line contact CB is formed, for example, in an elliptical shape for each bit line. That is, the trench of source line contact 300 has a larger area than the hole for bit line contact 310 in a plan view viewed from a substrate.

Here, in performing an RIE to form a hole or a trench pattern, an etching speed of a region in which an area of an opening is wide is faster than a region in which an area of an opening is narrow. This is because, for example, an etchant in RIE is likely to reach a bottom of a hole or a trench in a region of a wide region, and on the other hand, an etchant is unlikely to reach the bottom of a hole or a trench of a narrow region.

Accordingly, when the trench for source line contact 300 and the hole for bit line contact 310 are etched at the same time, the trench for source line contact 300 has a faster etching speed. In the embodiment, a step by the recess 105 is formed in the semiconductor substrate 100 between the source line side selection transistors SS. That is, the semiconductor substrate 100 in a region in which the trench for source line contact 300 is formed is provided to be lower than the semiconductor substrate 100 in a region in which the hole for bit line contact 310 is formed. That is, an etched film in formation of the trench for source line contact 300 is thicker than an etched film in formation of the hole for bit line contact 310.

Although an etching speed of the trench for source line contact is faster, due to a step of the recess 105, either of the hole for bit line contact 310 and the trench for source line contact 300 may process the first interlayer insulation film 290 up to the same extent (reach the stopper film 280).

When the recess 105 is not provided, if the hole for bit line contact 310 is etched to reach the stopper film 280, there is a possibility that the trench for source line contact 300 passes through the stopper film 280 to pass through the second impurity diffusion layer 260 of the semiconductor substrate 100. When the trench for source line contact passes through the second impurity diffusion layer 260, a junction leakage current increases, and thereby there is a possibility that the leakage current increases.

As described in a formation of the spacer 270 in FIG. 25, the semiconductor substrate 100 between the spacer 270 of the bit line side selection transistor SB (1) and the bit line side selection transistor SB (2) is etched. Therefore, the bit line contact CB is provided to have a bottom thereof in contact with a position lower than the semiconductor substrate 100 in a region in which a cell transistor is formed.

Thereafter, to form the structure illustrated in FIG. 29, a mask pattern is formed on the first interlayer insulation film 290, and the first interlayer insulation film 290 is etched by RIE. A first wiring trench 320 and a first wiring hole 325 are formed by the process.

Then, to form the structure illustrated in FIG. 30, the lower layer contact material is deposited, and an unnecessary contact material is removed while flattening is performed by CMP. Accordingly, the bit line contact CB and the source line contact SLC, the first wiring 335, and the first wiring contact 333 are formed. The lower layer contact material includes, for example, a metal film and a barrier metal layer. The metal film includes tungsten, copper, aluminum, or the like. The barrier metal layer includes, for example, titanium, tantalum, titanium nitride, tantalum nitride, or is a laminated layer of any of these.

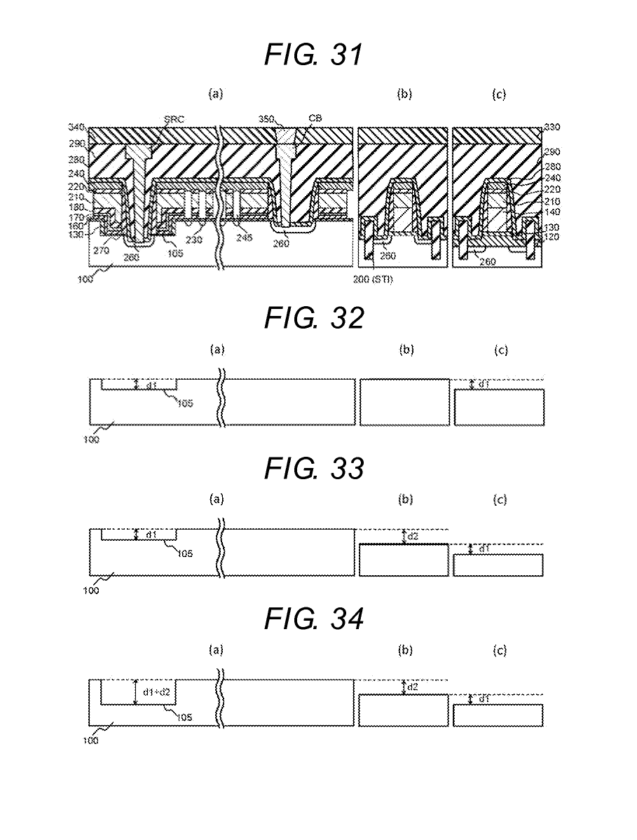

Then, as illustrated in FIG. 31, the second interlayer insulation film 340 is formed. A mask pattern is formed on the second interlayer insulation film 340, and is etched by RIE, thereby forming an upper contact hole. Then, the upper contact material is deposited and an unnecessary upper contact material is removed by the CMP, thereby forming an upper contact 350.

Hereinafter, various wiring layers or circuit elements are formed using a general manufacturing method. In this manner, the semiconductor memory device according to the embodiment is manufactured.

According to the semiconductor memory device according to the embodiment, as illustrated in FIG. 5, in a part of a region in which the source line side selection transistors SS (1) and SS (2) are formed and a region between the source line side selection transistors SS (1) and the source line side selection transistor SS (2), the recess 105 is provided in the semiconductor substrate 100.

The recess 105 is provided in the semiconductor substrate 100, whereby the source line side selection transistor SS is formed with the gate electrode, the gate insulating film, and the channel region, each having curved surfaces. That is, it is possible to form a transistor which has a long channel length relative to a transistor which has a flat gate electrode. That is, it is possible to form a selection transistor which has a long channel length and a good controllability.

In addition, as described in the manufacturing method, the source line contact SLC and the bit line contact CB are processed at the same time without over-etching problems.

As illustrated in FIG. 28, since the recess 105 is provided in the semiconductor substrate 100, the semiconductor substrate 100 under the trench for source line contact 300 is provided to be lower than the hole for bit line contact 310. Therefore, the trench for source line contact 300 has a larger area than the hole for bit line contact 310. Moreover, despite a fast etching speed, it is possible to stop a process on any of the hole for bit line contact 310 and the trench for source line contact 300 using the stopper film 280.

When the recess 105 is not provided, the trench for source line contact 300 is over etched, whereby there is a concern that a junction leakage is increased between the source line contact SLC and the second impurity diffusion layer 260.

Furthermore, according to the embodiment, the recess 105 may be formed without an addition of a new process.

As illustrated in FIG. 8, it is desirable that the semiconductor substrate 100 of the low voltage transistor region and the high voltage transistor region be lowered by etching. This is because, for example, it is better to make heights of a semiconductor substrate of the cell array cover film 190 and the peripheral cover film 150 be uniform so as to avoid problems that the rest of the element isolation film 200 experiences in the CMP when forming the element isolating area STI illustrated in FIG. 17. Therefore, it is necessary to form the semiconductor substrate 100 of the low voltage transistor region and the high voltage transistor region to be low in advance according to a film thickness formed in each region.

It is possible to form the recess 105 by etching the semiconductor substrate 100 at the same time as etching the semiconductor substrate 100 in a region in which the low voltage transistor and the high voltage transistor are formed as illustrated in FIG. 8. Accordingly, the recess 105 may be formed without adding a new process. The recess 105, however, may be formed by another process in other embodiments.

Hereinafter, a modification example will be described. In FIGS. 32 to 34, each part (a) illustrates a cross-section taken along line A-A′ (column direction) of FIG. 4, each part (b) illustrates a cross-section of the low voltage transistor of the peripheral circuit unit, and each part (c) illustrates a cross-section of the high voltage transistor of the peripheral circuit unit, respectively. In addition, FIGS. 32 to 34 have an aspect ratio different from that in FIG. 5 for convenience of description.

As a first modification example, as in FIG. 32, it is illustrated that an etching which forms the recess 105 and an etching on the semiconductor substrate 100 of the high voltage transistor region in FIG. 7 are performed at the same time.

In this case, an etching process which processes the semiconductor substrate 100 of the memory cell region, the low voltage transistor region, and the high voltage transistor region at the same time may be or may not be performed on the recess 105. FIG. 33 illustrates a case when the etching process is not performed, and FIG. 34 illustrates a case when the etching process is performed.

When the etching process is performed, as illustrated in FIG. 34, the recess 105 may be formed to be deeper. This is useful when an etching speed of the source line contact trench is faster than an etching speed of the bit line contact hole. Alternatively, it is possible to further improve controllability of the source line side selection transistor.

A second modification example will be described. In the embodiment, it is described that the peripheral circuit includes the low voltage transistor and the high voltage transistor. However, the peripheral circuit may include just one type of transistor. In this case, an etching which lowers the semiconductor substrate 100 in a region in which a transistor is formed and a formation of the recess 105 may be performed on the memory cell region at the same time.

A third modification example will be described. The recess 105 of the semiconductor substrate 100 is not limited to an interval between the source line side selection transistors SS and a partial region of a lower part of the gate electrode of the source line side selection transistor.

Since the hole for bit line contact and the trench for source line contact may be easily formed at the same time, it is sufficient if the recess 105 is formed at a lower part of the trench for source line contact. That is, the recess 105 may be formed only in a contact surface between the source line side selection transistors SS, or between the trench for source line contact and the semiconductor substrate 100.

On the contrary, the recess 105 may be extended. In this case, it is desirable not to be overlapped in a region under the gate electrode of the dummy memory cell transistor. This is because adverse effects that characteristics of a cell transistor vary and the like are concerned.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory cell transistors that are formed above a semiconductor substrate and are connected to each other in series;
first and second selection transistors formed respectively on either side of the memory cell transistors above the semiconductor substrate;
a source line contact formed adjacent the first selection transistor and having a bottom thereof in contact with the semiconductor substrate; and
a bit line contact formed adjacent the second selection transistor and having a bottom thereof in contact with the semiconductor substrate at a position higher than the bottom of the source line contact.

2. The device according to claim 1, wherein the source line contact has a line shape and the bit line contact has an elliptical shape.

3. The device according to claim 1, wherein each of the first and second selection transistors includes a gate electrode, a gate insulating film, and a channel region, each of which has a curved shape.

4. The device according to claim 1, wherein the first selection transistor is formed on a first portion of the semiconductor substrate and the second selection transistor is formed on a second portion of the semiconductor substrate that is higher than the first portion.

5. The device according to claim 4, wherein the first portion of the semiconductor substrate is higher than the bottom of the source line contact and lower than the bottom of the bit line contact, and the second portion of the semiconductor substrate is higher than the bottom of the bit line contact.

6. The device according to claim 1, wherein the memory cell transistors include dummy memory cell transistors.

7. The device according to claim 6, wherein each of the dummy memory cell transistors is directly adjacent to one of the first and second selection transistors.

8. A semiconductor memory device comprising:
a semiconductor substrate having a first region that is recessed from an upper surface thereof, a second region that is not recessed from the upper surface, and a memory cell region between the first and second regions;
a plurality of memory cell transistors that are formed in the memory cell region of the semiconductor substrate and are connected to each other in series;
a first selection transistor formed in the first region of the semiconductor substrate;
a source line contact formed adjacent the first selection transistor and in the first region of the semiconductor substrate; and
a second selection transistor formed in the second region of the semiconductor substrate;
a bit line contact formed adjacent the second selection transistor and in the second region of the semiconductor substrate.

9. The device according to claim 8, wherein the source line contact has a line shape and the bit line contact has an elliptical shape.

10. The device according to claim 8, wherein each of the first and second selection transistors includes a gate electrode, a gate insulating film, and a channel region, each of which has a curved shape.

11. The device according to claim 8, wherein a channel region of the first selection transistor is formed lower on the semiconductor substrate than that of the second selection transistor.

12. The device according to claim 11, wherein the channel region of the first selection transistor is higher than a bottom of the source line contact and lower than a bottom of the bit line contact, and the channel region of the second selection transistor is higher than the bottom of the bit line contact.

13. The device according to claim 8, wherein the memory cell transistors include dummy memory cell transistors.

14. The device according to claim 13, wherein each of the dummy memory cell transistors is directly adjacent to one of the first and second selection transistors.

15. A method of manufacturing a semiconductor memory device, comprising:
forming a recessed region on a surface of a semiconductor substrate;
forming a plurality of a plurality of memory cell transistors in a memory cell region of the semiconductor substrate;
forming a first selection transistor in the recess region and a second selection transistor in a non-recessed region of semiconductor substrate that is one a side of memory cell region opposite that of the recessed region; and
forming an opening for a source line contact in the recessed region and an opening for a bit line contact in the non-recessed region.

16. The method according to claim 15, wherein
the opening for the source line contact is a trench and the opening for the bit line contact is a hole.

17. The method according to claim 15, wherein
a bottom of the opening for the bit line contact is at a position higher than a bottom of the opening for the source line contact.

18. The method according to claim 15, further comprising:
forming a low voltage transistor and a high voltage transistor in a peripheral circuit region of the semiconductor substrate, wherein
the recessed region is formed at the same time a selective etching process is performed on the semiconductor substrate in connection with the forming of the low voltage transistor and the high voltage transistor in the peripheral circuit region.

19. The method according to claim 15, wherein the first and second selection transistors are each formed to have a curved gate electrode, a curved gate insulating film, and a curved channel region.

20. The method according to claim 15, wherein the first selection transistor is formed on a first portion of the semiconductor substrate and the second selection transistor is formed on a second portion of the semiconductor substrate that is higher than the first portion.
